(19) United States
(12) Patent Application Publication
(10) Pub. No.: US 2025/0373207 A1
(43) Pub. Date: Dec. 4, 2025

(54) COMPENSATION CIRCUIT FOR AMPLIFIER, METHOD FOR COMPENSATING AMPLIFIER, AND AMPLIFIER ASSEMBLY

(71) Applicant: SMARTER MICROELECTRONICS (SHANGHAI) CO., LTD., Shanghai (CN)

(72) Inventors: Yi YANG, Shanghai (CN); Zhenfei PENG, Shanghai (CN); Qiang SU, Shanghai (CN)

(73) Assignee: SMARTER MICROELECTRONICS (SHANGHAI) CO., LTD., Shanghai (CN)

(21) Appl. No.: 19/017,716

(22) Filed: Jan. 12, 2025

(30) Foreign Application Priority Data
Jun. 2, 2024 (CN) 202410702360.X

(51) Int. Cl. H03F 1/32; H03F 3/19

(52) U.S. Cl. CPC H03F 1/32; H03F 3/19; H03F 2200/451

(57) ABSTRACT

The present disclosure relates to the technical field of electronics. The embodiments of the present disclosure provide a compensation circuit for an amplifier, a method for compensating an amplifier, and an amplifier assembly. The compensation circuit for the amplifier includes a detection circuit, a control circuit and a phase compensation circuit. The detection circuit is connected to an input end of the amplifier, and is configured to detect an input power of an input signal of the amplifier. The control circuit is connected to the detection circuit, and is configured to output a control signal according to the detected input signal. The phase compensation circuit is connected to an output end of the control circuit, and is configured to change a capacitance between the input end of the amplifier and a ground node according to the control signal, to compensate for a phase of the amplifier in different directions.

### CROSS-REFERENCE TO RELATED APPLICATION

The present application claims priority to Chinese Patent Application No. 202410702360.X filed on Jun. 2, 2024, the disclosure of which is hereby incorporated by reference in its entirety.

### BACKGROUND

Under a condition of high power, the phase of the Power Amplifier (PA) itself will change, which causes linearity deterioration. The predistorter implements linearity improvement by compensating for the phase of the PA in advance. In some implementations, the effect of the linearity improvement is limited.

### SUMMARY

The present disclosure relates to the technical field of electronics, in particular to a compensation circuit for an amplifier, a method for compensating an amplifier and an amplifier assembly.

In view of the above, the embodiments of the present disclosure provide a compensation circuit for an amplifier. The compensation circuit for the amplifier includes a detection circuit, a control circuit and a phase compensation circuit. The detection circuit is connected to an input end of the amplifier, and is configured to detect an input power of an input signal of the amplifier. The control circuit is connected to the detection circuit, and is configured to output a control signal according to the detected input signal. The phase compensation circuit is connected to an output end of the control circuit, and is configured to change a capacitance between the input end of the amplifier and a ground node according to the control signal, to compensate for a phase of the amplifier in different directions.

In some embodiments, the control circuit includes a sub-control circuit. The sub-control circuit is connected to the detection circuit, and is configured to output a control signal positively and/or negatively associated with the detection signal according to the detection signal.

In some embodiments, the sub-control circuit includes a starting control circuit and a direction control circuit. The starting control circuit is connected to an output end of the detection circuit, and is configured to selectively transmit the detection signal to the direction control circuit according to the detected signal. The direction control circuit is connected to the starting control circuit, and is configured to generate the control signal that increases with an increase of the input power of the detection signal or decreases with the increase of the input power of the detection signal according to a received output signal of the starting control circuit.

In some embodiments, the phase compensation circuit is specifically configured to: increase the capacitance between the input end of the amplifier and a ground voltage according to an increase of the control signal, and decrease the capacitance between the input end of the amplifier and the ground voltage according to a decrease of the control signal.

In some embodiments, the control circuit at least includes the first sub-control circuit, the second sub-control circuit and a switching control circuit. The first sub-control circuit is connected to the detection circuit, and is configured to output the first control voltage that is proportional to the input power of the detected input signal according to the detected signal. The second sub-control circuit is connected to the detection circuit, and is configured to output the second control voltage that is inversely proportional to the input power of the detected input signal according to the detected signal. The switching control circuit is connected to the first sub-control circuit, the second sub-control circuit, and the phase compensation circuit, and is configured to control one of the first sub-control circuit or the second sub-control circuit to be connected to the phase compensation circuit.

In some embodiments, a starting control circuit of the first sub-control circuit includes the first transistor, and a direction control circuit of the first sub-control circuit includes the first resistor. A control end of the first transistor is connected to an output end of the detection circuit, one controlled end of the first transistor is connected to a power supply node, and the other controlled end of the first transistor is connected to the ground node through the first resistor.

In some embodiments, a starting control circuit of the second sub-control circuit includes the second transistor, and a direction control circuit of the second sub-control circuit includes the second resistor. A control end of the second transistor is connected to an output end of the detection circuit, one controlled end of the second transistor is connected to the second resistor, and other controlled end of the second transistor is connected to the ground node. One end of the second resistor is connected to a power supply node, and other end of the second resistor is connected to the controlled end of the second transistor and the switching control circuit.

In some embodiments, the second sub-control circuit further includes the third transistor. The control end and one controlled end of the third transistor are both connected to the power supply node, and other controlled end of the third transistor is connected to the second transistor through the second resistor.

In some embodiments, the switching control circuit at least includes the first switch and the second switch. The first switch is connected to the first sub-control circuit and the phase compensation circuit, and the second switch is connected to the second sub-control circuit and the phase compensation circuit. When the first switch is in a connected state and the second switch is in a disconnected state, the first sub-control circuit is controlled to be connected to the phase compensation circuit. When the first switch is in the disconnected state and the second switch is in the connected state, the second sub-control circuit is controlled to be connected to the phase compensation circuit.

In some embodiments, the compensation circuit of the amplifier further includes a compensation amplitude adjustment circuit. Two ends of the compensation amplitude adjustment circuit are connected to the control circuit and the phase compensation circuit, respectively, to adjust an amplitude of a phase compensation.

In some embodiments, the compensation circuit of the amplifier further includes a bandwidth compensation circuit. The bandwidth compensation circuit is connected to both the detection circuit and the control circuit, and is configured to compensate for a bandwidth of the amplifier.

In some embodiments, the detection circuit includes a bias circuit, a sampling circuit, and a power measurement circuit. The bias circuit is connected to the power measurement circuit, and is configured to provide a bias signal to the power measurement circuit. The sampling circuit is connected to the input end of the amplifier, and is configured to perform sampling on the input signal of the amplifier. The power measurement circuit is configured to output a detection signal according to the sampled input signal under an action of the bias signal. The detection signal is associated with the input power of the amplifier.

In some embodiments, the bias circuit is connected to the ground node through a current source with a positive temperature coefficient.

The embodiments of the present disclosure further provide an amplifier assembly. The amplifier assembly includes an amplifier and a compensation circuit for the amplifier provided by the embodiments of the present disclosure. The compensation circuit for the amplifier is connected to an input end of the amplifier.

In some embodiments, the amplifier includes an input matching circuit, a driver stage amplifier, and a power stage amplifier that are sequentially connected in series. The compensation circuit for the amplifier is connected to an input end of the input matching circuit, or is connected between the input matching circuit and the driver stage amplifier, or is connected between the driver stage amplifier and the power stage amplifier.

In some embodiments, there are a plurality of compensation circuits for the amplifier, and the plurality of compensation circuits are connected to different positions of the amplifier.

In some embodiments, the amplifier assembly further includes a gain compensation circuit. Two ends of the gain compensation circuit are connected to the input end of the amplifier and a bias end of the amplifier, respectively, and the gain compensation circuit is configured to compensate for a gain of the amplifier.

The embodiments of the present disclosure further provide a method for compensating an amplifier. The method is applied to a compensation circuit for the amplifier including a detection circuit, a control circuit and a phase compensation circuit. The method includes the following operations. The detection circuit detects an input power of an input signal of the amplifier. The control circuit outputs a control signal according to the detected input signal. The phase compensation circuit changes a capacitance between an input end of the amplifier and a ground node according to the control signal to compensate a phase of the amplifier in different directions.

In various embodiments of the present disclosure, the compensation circuit for the amplifier detects the input power of the input signal of the amplifier through the detection circuit, generates a control signal through the control circuit, and finally controls to intervene phase compensation with the appropriate direction when the amplifier reaches a certain input power through the phase compensation circuit. In the embodiments of the present disclosure, the phase change of the amplifier is associated with the input power of the amplifier. When the input power is low, the phase linearity is good and can be basically maintained in a straight line. When the input power increases to a certain extent, the phase starts to change and the phase linearity deteriorates. In the embodiments of the present disclosure, the control signal generated according to the detected input power is associated with the case that the phase of the amplifier starts to change and can indicate the direction of the phase compensation. In this way, the phase linearity of the amplifier can be better improved.

### BRIEF DESCRIPTION OF THE DRAWINGS

FIG. 1A is the first schematic diagram including an analog predistortion (APD) circuit according to an embodiment of the present disclosure.

FIG. 1B is the second schematic diagram including an APD circuit according to an embodiment of the present disclosure.

FIG. 2 is the first schematic diagram of a hardware composition including a compensation circuit for an amplifier (APD-AM circuit) according to an embodiment of the present disclosure.

FIG. 3A is the second schematic diagram of a hardware composition including a compensation circuit for an amplifier (APD-AM circuit) according to an embodiment of the present disclosure.

FIG. 3B is a schematic diagram of a connection relationship between a compensation circuit for an amplifier (APD-AM circuit) and the amplifier according to an embodiment of the present disclosure.

FIG. 4A is the first schematic diagram including a compensation circuit for an amplifier (APD-AM circuit) according to an embodiment of the present disclosure.

FIG. 4B is the second schematic diagram including a compensation circuit for an amplifier (APD-AM circuit) according to an embodiment of the present disclosure.

FIG. 4C is the third schematic diagram including a compensation circuit for an amplifier (APD-AM circuit) according to an embodiment of the present disclosure.

FIG. 5 is a schematic diagram of compensation for the AMAM curve of PA through the APD-AM circuit according to an embodiment of the present disclosure.

FIG. 6 is a flowchart of an implementation of a method for compensating an amplifier applied to the APD-AM circuit according to an embodiment of the present disclosure.

FIG. 7 is the first schematic diagram of a hardware composition including a compensation circuit for an amplifier (APD-PM circuit) according to an embodiment of the present disclosure.

FIG. 8A is the second schematic diagram of a hardware composition including a compensation circuit for an amplifier (APD-PM circuit) according to an embodiment of the present disclosure.

FIG. 8B is a schematic diagram of a connection relationship between a compensation circuit for an amplifier (APD-PM circuit) and the amplifier according to an embodiment of the present disclosure.

FIG. 9A is the first schematic diagram including a compensation circuit for an amplifier (APD-PM circuit) according to an embodiment of the present disclosure.

FIG. 9B is the second schematic diagram including a compensation circuit for an amplifier (APD-PM circuit) according to an embodiment of the present disclosure.

FIG. 9C is the third schematic diagram including a compensation circuit for an amplifier (APD-PM circuit) according to an embodiment of the present disclosure.

FIG. 10A is the first schematic diagram of compensation for the AMPM curve of PA through the APD-PM circuit according to an embodiment of the present disclosure.

FIG. 10B is the second schematic diagram of compensation for the AMPM curve of PA through the APD-PM circuit according to an embodiment of the present disclosure.

FIG. 11 is a flowchart of an implementation of a method for compensating for an amplifier applied to the APD-AM circuit according to an embodiment of the present disclosure.

FIG. 12 is the first schematic diagram including a connection relationship among an APD-AM circuit, the APD-PM circuit and the amplifier according to an embodiment of the present disclosure.

FIG. 13A is the first schematic diagram of compensation for an AMAM curve of PA through an APD-AM circuit and an APD-PM circuit according to an embodiment of the present disclosure.

FIG. 13B is the first schematic diagram of compensation for an AMPM curve of PA through an APD-AM circuit and an APD-PM circuit according to an embodiment of the present disclosure.

FIG. 14 is the second schematic diagram including a connection relationship among an APD-AM circuit, the APD-PM circuit and the amplifier according to an embodiment of the present disclosure.

FIG. 15A is the second schematic diagram of compensation for an AMAM curve of PA through an APD-AM circuit and an APD-PM circuit according to an embodiment of the present disclosure.

FIG. 15B is the second schematic diagram of compensation for an AMPM curve of PA through an APD-AM circuit and an APD-PM circuit according to an embodiment of the present disclosure.

### DETAILED DESCRIPTION

Hereinafter, the present disclosure will be further described in detail with reference to the accompanying drawings and examples. It should be understood that the following specific embodiments described in the present disclosure are merely for illustration of the present disclosure, and are not intended to limit the present disclosure.

The amplifier mentioned in the embodiments of the present disclosure includes, but is not limited to, the PA, and any amplifier having similar gain and/or phase compensation requirements is used. Hereinafter, only the PA will be described as an example.

Under a condition of high power, the gain of the PA itself will decrease, which causes the linearity deterioration. The gain of PA may be compensated in advance by the predistortion technology to implement linearity improvement. The predistortion technology mainly includes APD technology and digital predistortion (DPD) technology. The APD mainly implements the function of predistortion through the analog circuits, which has the advantages of simple circuit structure, low power consumption, small area and being integrable in Radio Frequency (RF) front-end module. Based on this, the present disclosure mainly relates to the APD technology hereinafter.

In the 5th Generation Mobile Communication Technology (5G), the requirements for spectral purity and power efficiency of the PA have been greatly increased. However, the linearity and efficiency of PA are usually mutually-restrained. In order to implement the linearity improvement without losing efficiency, various linearity optimization technologies are proposed. The aforementioned APD is a method that has been widely adopted and proven to be effective.

If the APD is adopted to greatly improve the linearity of PA, it is required to compensate for the PA when the PA just starts entering the gain compression region (i.e., the gain decrease region), and the amplitude of compensation needs to be equal to the amplitude of the gain decrease of the PA, and the phase of the compensation needs to be opposite to the phase of the gain decrease of the PA. In some implementations of APD, the above requirements are not met, so the improvement effect on linearity of the PA is limited. Some specific implementations of APD are exemplified below.

In some embodiments, the PA is provided with a positive gain and a negative phase by connecting a diode in series or in parallel to finally implement the function of predistortion.

In some embodiments, similar to the previous embodiment, a field effect transistor or a triode is used to implement the same function as the diode in the previous embodiment.

In some embodiments, a variable resistor and a capacitor that are connected in parallel are used to implement the same function as the diode in the previous embodiment.

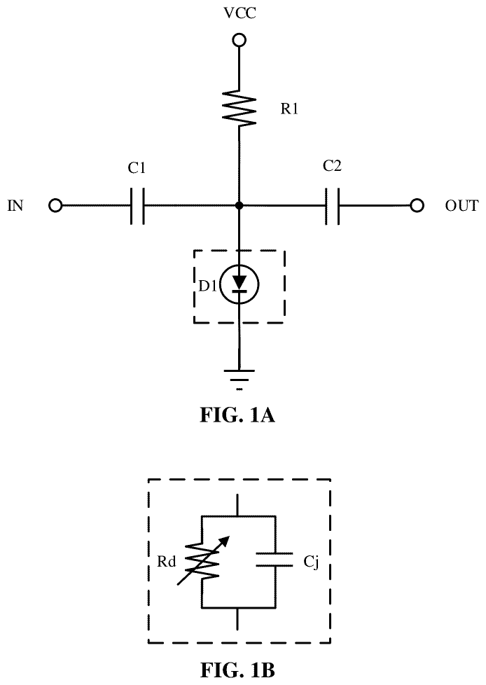

FIG. 1A is the first schematic diagram including an APD circuit according to an embodiment of the present disclosure. FIG. 1B is the second schematic diagram including an APD circuit according to an embodiment of the present disclosure. For example, as illustrated in FIG. 1A, the function of APD is implemented by connecting a diode in series or in parallel, and the diode illustrated in the dashed box of FIG. 1A may be equivalent to the parallel structure of the variable resistor and capacitor illustrated in the dashed box of FIG. 1B. The ground loss is reduced by increasing the resistance value of the variable resistor, thereby implementing the gain compensation for the PA.

However, according to the above embodiment for APD, the compensation cannot be just intervened when the PA enters the gain compression region, and a compensation amount corresponding to the gain attenuation amount of the PA cannot be provided. Therefore, the linearity improvement effect on the PA is limited, and especially for the PA whose performance is basically converged, the linearity improvement effect is significantly weak.

In addition, only the AMAM of PA is compensated based on the above embodiment, which usually leads to the deterioration of the AMPM of PA, and finally leads to the deterioration of linearity of the PA.

In view of at least one of the above problems, the embodiments of the present disclosure propose an improved APD circuit. The APD circuit includes an APD-AM circuit, which may detect the input power of the amplifier, and immediately compensate the amplifier when it is found that the amplifier enters the gain compression region. The APD-AM circuit mainly implements the “fixed-point”, “equivalent value” and “opposite phase” compensation for the gain of PA, thereby maximizing the optimization of the AMAM curve of PA.

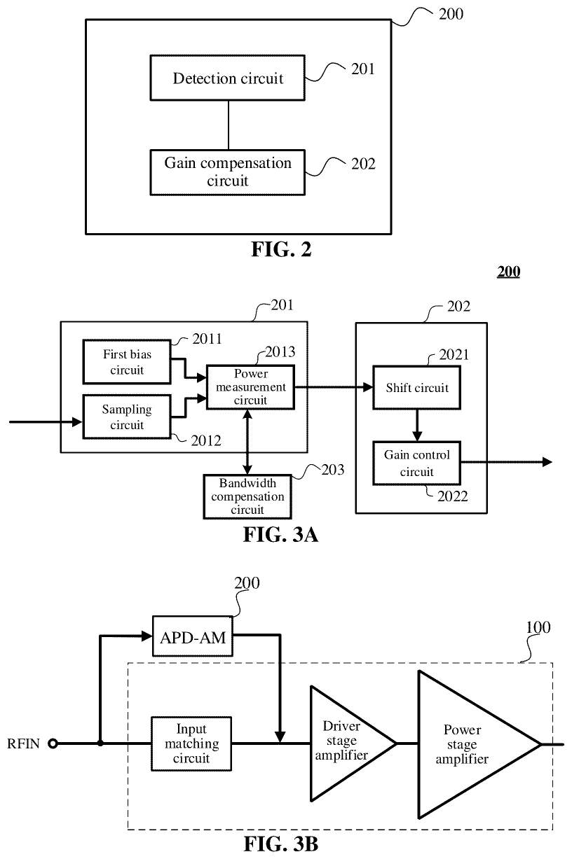

The compensation circuit for the amplifier (APD-AM circuit) will be described in detail below with reference to FIG. 2 to FIG. 4C.

The embodiments of the present disclosure provide a compensation circuit for an amplifier. As illustrated in FIG. 2, the compensation circuit 200 for the amplifier includes a detection circuit 201 and a gain compensation circuit 202. The detection circuit 201 is connected to an input end of the amplifier, and is configured to detect an input power of an input signal of the amplifier. The gain compensation circuit 202 is connected to the detection circuit 201, and is configured to: when a detected input power is greater than or equal to the first preset threshold, apply the first bias signal to the amplifier to compensate a gain of the amplifier; and when the detected input power is less than the first preset threshold, stop applying the first bias signal to the amplifier. The first preset threshold is associated with the case that the gain of the amplifier starts to decrease.

As illustrated in FIG. 3B, the compensation circuit 200 for the amplifier (APD-AM circuit) in the embodiments of the present disclosure may be connected across two ends of the input matching circuit of the amplifier, which can be integrable in RF front-end modules.

It should be noted that the compensation circuit may be located between the input matching circuit and the driver stage amplifier, or between the driver stage amplifier and the power stage amplifier, or may be connected across two ends of the driver stage amplifier, or may be connected across the input end of the input matching circuit and the output end of the driver stage amplifier. When the compensation circuit is connected to different positions in the amplifier circuit, the detection circuit is configured to detect the related input power, i.e., the input end of the amplifier, which may be understood as the RF signal RFIN input end, the input end of the driver stage amplifier, or the input end of the power stage amplifier. The input signal and power are the corresponding signal and input power.

In other embodiments, there may be multiple compensation circuits, and the positions of the multiple compensation circuits are different. For example, there are two compensation circuits, one of the two compensation circuits is connected across the input matching circuit and the other compensation circuit is located between the driver stage amplifier and the power stage amplifier, so as to compensate for the driver stage amplifier and the power stage amplifier respectively.

As previously, the gain change of the amplifier is associated with the input power of the amplifier. When the input power is less, the gain linearity is better, and when the input power increases to a certain extent, the gain starts to decrease, and the gain linearly becomes worse. In the embodiments of the present disclosure, the first preset threshold associated with the cast that the gain of the amplifier starts to decrease is set, for example, the first preset threshold may be equal to the value of the input power of the PA corresponding to the case that the gain of the amplifier starts to decrease. Therefore, the compensation circuit for the amplifier provided in the embodiments of the present disclosure may detect the input power of the input signal of the amplifier through the detection circuit 201, and accurately control to intervene the gain compensation when the amplifier reaches a certain input power through the gain compensation circuit 202. When the compensation circuits are connected to different positions of the amplifier circuit, the first preset threshold is associated with the power of the respective position. That is, in this case, the first preset threshold is needed to be properly adjusted, while the moment of starting the compensation is still the moment that the gain decreases.

Here, the detection circuit 201 is mainly configured to detect the input power Pin of the input signal of the amplifier. In some embodiments, as illustrated in FIG. 3A, the detection circuit 201 includes the first bias circuit 2011, a sampling circuit 2012, and a power measurement circuit 2013. The first bias circuit 2011 is connected to the power measurement circuit, and is configured to provide the second bias signal to the power measurement circuit. The sampling circuit 2012 connected to the input end of the amplifier, and is configured to perform sampling on an input signal of the amplifier. The power measurement circuit 2013 is configured to output a detection signal according to a sampled input signal under an action of the second bias signal. The detection signal is associated with the input power of the amplifier.

Exemplarily, as illustrated in FIG. 3A, the input signal of the amplifier, i.e., the RF signal RFIN, is coupled into the power measurement circuit 2013 through the sampling circuit 2012. Meanwhile, the first bias circuit 2011 provides the second bias signal to the power measurement circuit 2013. After receiving the signals from the first bias circuit 2011 and the sampling circuit 2012, the power measurement circuit 2013 outputs a detection signal that may be used to characterize the input power Pin of the input signal of the amplifier. The detection signal is associated with the input power of the amplifier. In some embodiments, the detection signal is a current signal, and the current signal is positively associated with the input power of the amplifier.

In some specific embodiments, the sampling circuit 2012 includes the second capacitor and the power measurement circuit 2013 includes the fourth transistor. One end of the second capacitor is connected to the input end of the amplifier, and the other end of the second capacitor is connected to a control end of the fourth transistor. One controlled end of the fourth transistor is connected to a power supply node, and the other controlled end of the fourth transistor is taken as an output end to be connected to the gain compensation circuit 202.

Here, the adjustment of the amplification factor of the fourth transistor, i.e., the adjustment of the ratio of the power of the detection signal output by the fourth transistor to the input power of the amplifier, may be implemented by adjusting the parameter of the fourth transistor, such as the aspect ratio. It is to be understood that when the input signal is fixed, the greater the amplification factor of the fourth transistor is, the greater the output detection signal is and the stronger the gain compensation effect is, and the less the amplification factor of the fourth transistor is, the less the output detection signal is and the weaker the gain compensation effect is. Based on this, the gain compensation amount may be adjusted by adjusting the parameter of the fourth transistor according to the actual demand.

In some specific embodiments, the fourth transistor may be a P-type MOS transistor. The source of the P-type MOS transistor is connected to the power supply node AVDD, and the drain of the P-type MOS transistor is connected to the gain compensation circuit 202.

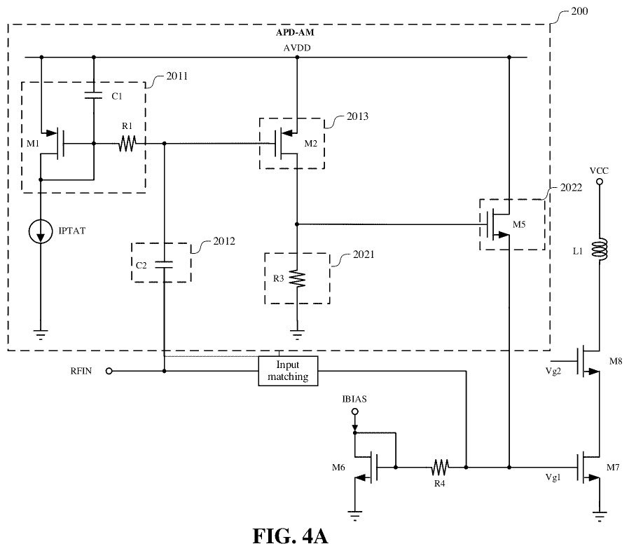

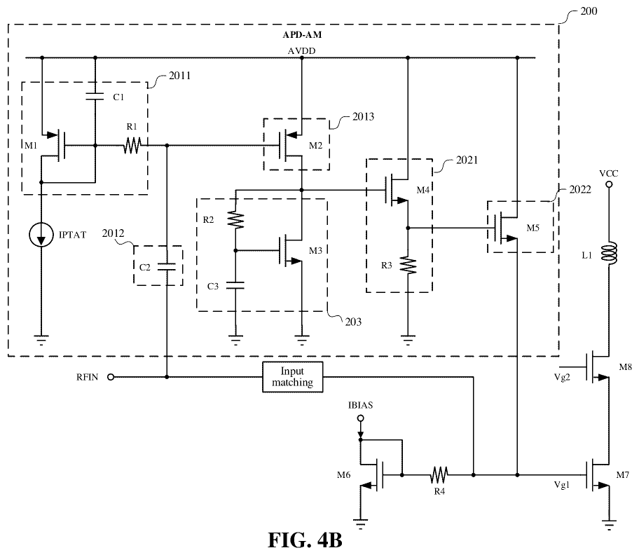

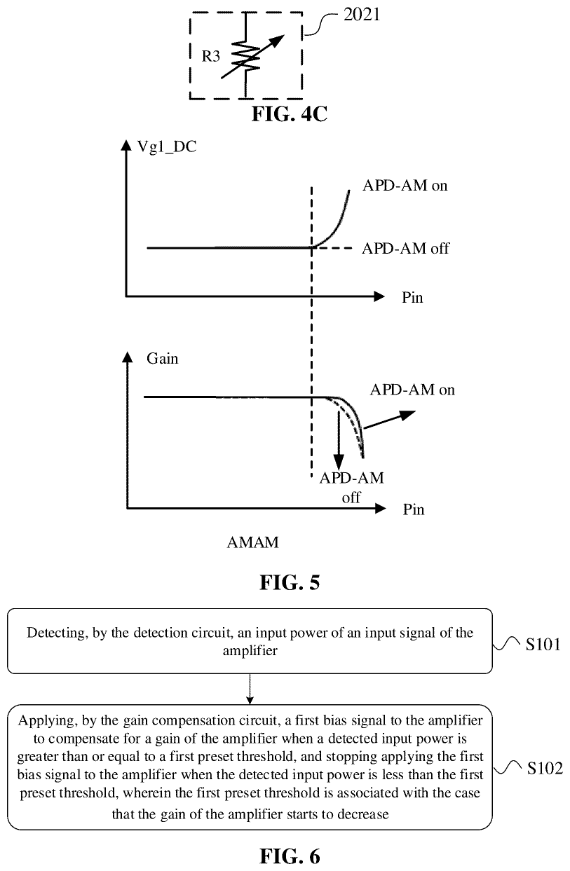

Exemplarily, as illustrated in FIG. 4A and FIG. 4B, the second capacitor C2 is configured to perform sampling on the input signal of the PA, i.e., the RF signal RFIN. The input signal is coupled into the APD-AM circuit, specifically into the gate of the fourth transistor M2. M2, as a power detection transistor, outputs a detection signal that is positively associated with the power of the RF signal, and transmits the detection signal to the shift circuit and the bandwidth compensation circuit (if there is a bandwidth compensation circuit). In the present embodiment, the output detection signal is a current signal, and in other embodiments, the detection signal may be converted into a voltage signal by connecting the fourth transistor with a load in series, which is not limited in the present disclosure.

In some specific embodiments, the first bias circuit 2011 includes the fifth transistor. One controlled end of the fifth transistor is connected to the power supply node, and the other controlled end of the fifth transistor is connected to its own control end and connected to the ground node through a current source. A control end of the fifth transistor is connected to the power measurement circuit 2013.

In some specific embodiments, the first bias circuit 2011 further includes the third capacitor and the third resistor. One end of the third capacitor is connected to the power supply node, and the other end of the third capacitor is connected to the control end of the fifth transistor. One end of the third resistor is connected to the control end of the fifth transistor and the third capacitor, and the other end of the third resistor is connected to the power measurement circuit 2013.

In some specific embodiments, the fifth transistor may be a P-type MOS transistor. The source of the P-type MOS transistor is connected to the power supply node AVDD, and the drain of the P-type MOS transistor is short circuited to its own gate and connected to the ground node through a current source.

Exemplarily, as illustrated in FIG. 4A and FIG. 4B, the fifth transistor M1, the third capacitor C1, and the third resistor R1 are taken as the first bias circuit to provide a desired second bias signal to the power detection transistor M2. R1 and C1 form a filter circuit to isolate the RF signal from the direct current (DC) power supply signal of the power supply node. It should be noted that in some embodiments, the third capacitor C1 and the third resistor R1 may be omitted. When the third capacitor C1 and the third resistor R1 are omitted, the gate of the fifth transistor M1 is directly connected to the power measurement circuit 2013.

In some embodiments, the first bias circuit 2011 is connected to the ground node through a current source with a positive temperature coefficient. That is, the other controlled end of the fifth transistor is connected to the ground node through a current source with a positive temperature coefficient.

Exemplarily, as illustrated in FIG. 4A and FIG. 4B, the other controlled end of the fifth transistor M1 is connected to the ground node through a current source IPTAT with a positive temperature coefficient.

It is to be understood that under a condition of high power, the heat generated by the PA will increase, which causes the temperature around PA to rise. After the IPTAT is introduced, when the temperature rises, the IPTAT increases. Under the same condition, the voltage of the gate of M5 (i.e., the first transistor of the gain control circuit 2022) illustrated in FIG. 4A and FIG. 4B is greater, so the compensation amplitude for the PA is greater. In this way, the compensation amplitude of the APD-AM circuit for the PA can be increased under the condition of high power.

Here, the gain compensation circuit 202 is mainly configured to perform appropriate gain compensation at an appropriate moment. In some embodiments, the gain compensation circuit 202 includes the shift circuit 2021 and a gain control circuit 2022. The shift circuit 2021 is connected to an output end of the detection circuit 201, and is configured to perform shift processing on the detected signal. The gain control circuit 2022 is connected to the shift circuit 2021, and is configured to selectively apply the first bias signal to the amplifier according to the shifted signal. The shifted signal causes that the first bias signal is started to be applied to the amplifier when the detected input power is equal to the first preset threshold.

Exemplarily, as illustrated in FIG. 3A, the shift circuit 2021 of the gain compensation circuit 202 receives a signal outputted by the detection circuit 201 for characterizing the input power Pin of the input signal of the amplifier. In the embodiments of the present disclosure, the shift circuit 2021 is set, and the signal output by the detection circuit 201 firstly enters the shift circuit for shifting, and the shifted signal may provide an accurate static operating point for the gain control circuit 2022, so that the gain control circuit 2022 can accurately compensate the first bias signal to the PA when the gain of the PA starts to decrease.

In some embodiments, the shift circuit 2021 includes the first resistor. One end of the first resistor is connected to the output end of the detection circuit and the input end of the gain control circuit, and the other end of the first resistor is connected to the ground node. The gain control circuit 2022 includes the first transistor. The control end of the first transistor is connected to the first resistor, one controlled end of the first transistor is connected to the power supply node, and the other controlled end of the first transistor is connected to the bias end of the amplifier.

In some specific embodiments, the first transistor may be an N-type MOS transistor. The drain of the N-type MOS transistor is connected to the power supply node AVDD, and the source of the N-type MOS transistor is connected to the node after impedance matching is performed at the input end of the amplifier.

Exemplarily, as illustrated in FIG. 4A, the first resistor R3 is configured to process the signal output by the detection circuit 201 for characterizing the input signal of the amplifier. The first transistor M5 is enabled to be turned on just when the voltage output to the gate of the first transistor M5 is the value with the input power corresponding to the case that the gain of the amplifier starts to decrease by adjusting the resistance of R3, so that the first bias signal used for gain compensation may be applied to the amplifier.

It should be noted that the function of the first transistor M5 here is mainly to control whether to apply the first bias signal to the amplifier. In some embodiments, the amplification factor of M5 may be approximately 1, or may be other values. When the first transistor M5 is turned on, the power supply signal on the power supply node provides power for M5, and the power supply signal after performing the signal processing by the R3 is applied to the gate of M7 of the amplifier. Meanwhile, depending on the difference of the detection signal output by the detection circuit, the current output from the first transistor M5 to the amplifier is different (the greater the signal coupled from C2 to the gate of M2 is, the greater the current injected from the source of the first transistor M5 into the amplifier), and the injected current causes the voltage of the gate of M7 to increase on the basis of the bias voltage, that is, the bias voltage of PA increases, such that the compensation for the decrease of gain of the PA is implemented, and the compensation amount may be adjusted according to the strength of the input power of the detected input signal.

It should be noted that the first resistor R3 in FIG. 4A may be a fixed resistor or a variable resistor illustrated in FIG. 4C. For example, when the consistency of the relationship between the input power and the gain of each amplifier in a batch of amplifiers is relatively good, and the consistency of the conduction threshold of the first transistor M5 is relatively good, the fixed resistor may be used to implement the shift. For another example, when there is a difference in the consistency of the relationship between the input power and the gain of each amplifier in a batch of amplifiers, and/or there is a difference in the conduction threshold of the first transistor M5, a variable resistor may be used, each amplifier is adjusted before leaving the factory to implement a shift matching the respective situation. For another example, when the relationship between the input power of the amplifier and the gain and/or the conduction threshold of the first transistor M5 drift, the variable resistor may be used to compensate for the drift.

In some embodiments, the shift circuit 2021 further includes the second transistor. The control end of the second transistor is connected to the output end of the detection circuit, one controlled end of the second transistor is connected to the power supply node, and the other controlled end of the second transistor is connected to the ground node through the first resistor. The control end of the first transistor is connected to both the second transistor and the first resistor.

In some specific embodiments, the second transistor may be an N-type MOS transistor. The drain of the N-type MOS transistor is connected to the power supply node AVDD, and the source of the N-type MOS transistor is connected to the gate of the first transistor.

Exemplarily, as illustrated in FIG. 4B, the second transistor M4 and the first resistor R3 cause that the gain of the PA is compensated through the first transistor M5 after the gain compression of the PA starts to appear by setting a suitable static operating point, so as to maximize the magnitude of linearity improvement. M4 and R3 are taken as a shift circuit to set a suitable static bias for M5. Generally, the resistance of the R3 is set to be less, so that M5 works in the cut-off area under a condition of low power, thus the APD-AM circuit will not compensate for PA at this case until the power increases to the first preset value, the gain of PA starts to decrease, M5 is turned on, and the APD-AM starts to compensate for the PA to implement the linear optimization.

It should be noted that the first resistor R3 in FIG. 4B may be a fixed resistor or a variable resistor illustrated in FIG. 4C.

It should be noted that two or more MOS transistors such as M4 and M5 may also be set. On the one hand, the voltage drop of the output by the M2 may be increased, and the connection between the power detection transistor M2 and the gain turn-on control transistor M5 may be better implemented.

It should be noted that the compensation amount of the compensation circuit 200 of the amplifier (APD-AM circuit) in the embodiments of the present disclosure may be adjusted by adjusting the parameters of various components, such as M2, M3, M4, M5, and R3, specifically, for example, the aspect ratio of the M2 as described above.

In some embodiments, the compensation circuit 200 of the amplifier further includes a bandwidth compensation circuit 203. The bandwidth compensation circuit 203 is connected to the output end of the detection circuit 201 and the input end of the gain compensation circuit 202, and is configured to compensate for the bandwidth of the predistortion circuit.

In some embodiments, the detection signal is a current signal, and the bandwidth compensation circuit 203 is further configured to convert the detection signal into a voltage signal.

In some specific embodiments, as illustrated in FIG. 4B, the bandwidth compensation circuit 203 includes the third transistor M3, the second resistor R2, and the first capacitor C3. The second resistor R2 and the first capacitor C3 are connected in series between the output end of the detection circuit 201 and the ground node. The control end of the third transistor M3 is connected to both the second resistor R2 and the first capacitor C3. One controlled end of the third transistor M3 is connected to the output end of the detection circuit, and the other controlled end of the third transistor M3 is connected to the ground node.

In some specific embodiments, the third transistor may be an N-type MOS transistor. The drain of the N-type MOS transistor is connected to the output end of the detection circuit, and the source of the N-type MOS transistor is connected to the ground node.

Here, the principle of phase compensation by the bandwidth compensation circuit 203 is as follows. The phase of the detection circuit is compensated by setting appropriate values of R2 and C3, so that the effect of bandwidth compensation is obtained. In some embodiments, R2 may be a variable resistor and/or C3 may be a variable capacitor, such that the phase is compensated according to different bands and modes. The parameters of various components used for the compensation may be adjustable to compensate different signals accordingly. It should be noted that the bandwidth compensation circuit 203 may increase the bandwidth, while the subsequent gain compensation is not affected. Therefore, the bandwidth compensation circuit 203 may also be omitted, and when the detection signal is a current signal, the bandwidth compensation circuit may be replaced by a ground resistor.

FIG. 5 is a schematic diagram of compensation for the AMAM curve of PA through the APD-AM circuit according to an embodiment of the present disclosure. It should be noted that the abscissa in FIG. 5 is the input frequency of the amplifier, the ordinate in the upper diagram in FIG. 5 is the DC voltage at the position where the first bias signal is applied in the amplifier, and the ordinate in the lower diagram in FIG. 5 is the gain of the amplifier. It can be seen that after the APD-AM circuit is turned on, the voltage at the position where the first bias signal is applied in the PA is obviously increased, and the linear region of gain keeps longer.

The embodiments of the present disclosure further provide an amplifier assembly. As illustrated in FIG. 3B, the amplifier assembly includes an amplifier 100 and the compensation circuit 200 of the amplifier (APD-AM circuit) provided by the embodiments of the present disclosure. The detection circuit of the compensation circuit for the amplifier is connected to the input end of the amplifier, and is configured to detect the input power of the input signal. The gain compensation circuit of the compensation circuit for the amplifier is configured to apply the first bias signal to the bias end of the amplifier.

In some embodiments, the amplifier 100 may include an input matching circuit, a driver stage amplifier, and a power stage amplifier that are sequentially connected in series. The compensation circuit for the amplifier is connected at two ends of the drive stage amplifier, or is connected between the input matching circuit and the driver stage amplifier, or is connected to two ends of the driver stage amplifier, or is connected between the driver stage amplifier and the power stage amplifier, or is connected between the input end of the input matching circuit and the output end of the drive stage amplifier.

It should be noted that when the compensation circuits are connected to different positions in the amplifier circuit, the detection circuit is configured to detect the respective input power, i.e., the input end of the amplifier, which may be understood as the radio frequency signal RFIN input end, the input end of the driver stage amplifier, or the input end of the power stage amplifier. The input signal and power are corresponding signal and input power.

In some embodiments, there are multiple compensation circuits of the amplifier, and the multiple compensation circuits are connected to different positions of the amplifier.

In some embodiments, the amplifier assembly illustrated in FIG. 12 further includes an APD-PM circuit 300. The APD-PM circuit 300 is connected to the input end of the amplifier, and is configured to compensate for the phase of the amplifier.

Here, the phase compensation circuit 300 will be described in detail below. FIG. 12 illustrates a case where the compensation circuit for the amplifier is connected to two ends of the drive stage amplifier, and the phase compensation circuit 300 is connected to the input end of the input matching circuit. The embodiments of the present disclosure further provide a method for compensating an amplifier. The method is applied to a compensation circuit for the amplifier (APD-AM circuit). The compensation circuit for the amplifier (APD-AM circuit) includes a detection circuit and a gain compensation circuit. As illustrated in FIG. 6, the method for compensating the amplifier includes the following operations.

In operation S101, the detection circuit detects an input power of an input signal of the amplifier.

In operation S102, when a detected input power is greater than or equal to the first preset threshold, the gain compensation circuit applies the first bias signal to the amplifier to compensate for the gain of the amplifier, and stops applying the first bias signal to the amplifier when the detected input power is less than the first preset threshold. The first preset threshold is associated with a case that the gain of the amplifier starts to decrease.

It should be noted that the specific implementation of the compensation circuit for the amplifier (APD-AM circuit) in the above embodiment of the amplifier assembly and the above embodiment of the method for compensating the amplifier may be understood with reference to the specific implementation of the foregoing compensation circuit for the amplifier (APD-AM circuit), which will not be elaborated here.

The linearity of PA is not only reflected in gain linearity, but also in phase linearity. Similarly, under the condition of high power, the phase of the PA itself will change (advance or lag), which causes linearity deterioration. The phase of the PA may be compensated by predistortion technology to implement the linearity improvement.

In view of the above problems, the embodiments of the present disclosure propose an improved APD circuit. The APD circuit includes an APD-PM circuit, which may detect the input power of the amplifier, and immediately performs the compensation on the phase of the amplifier in a positive direction or a negative direction when it is found that the phase of the amplifier starts to change, thereby maximizing the optimization of the AMPM curve of the PA.

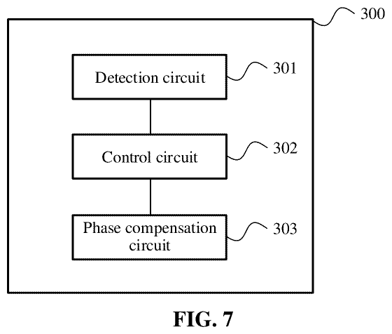

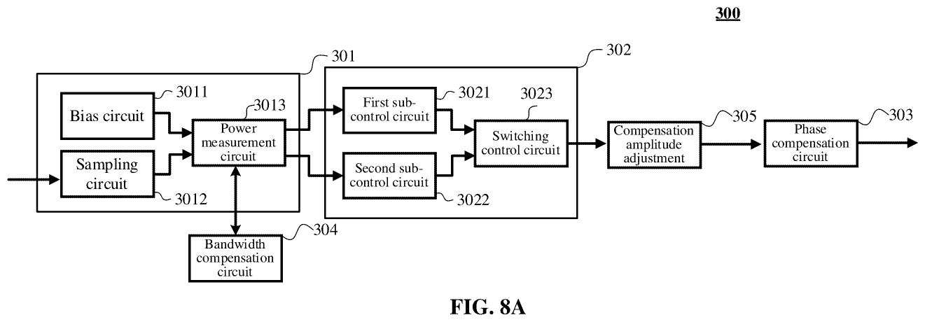

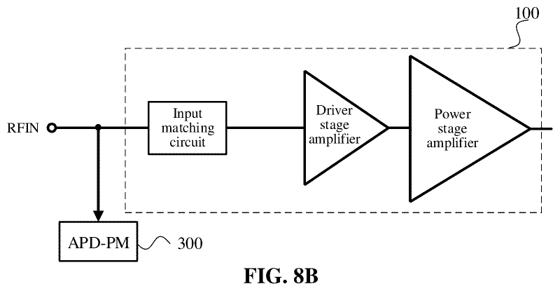

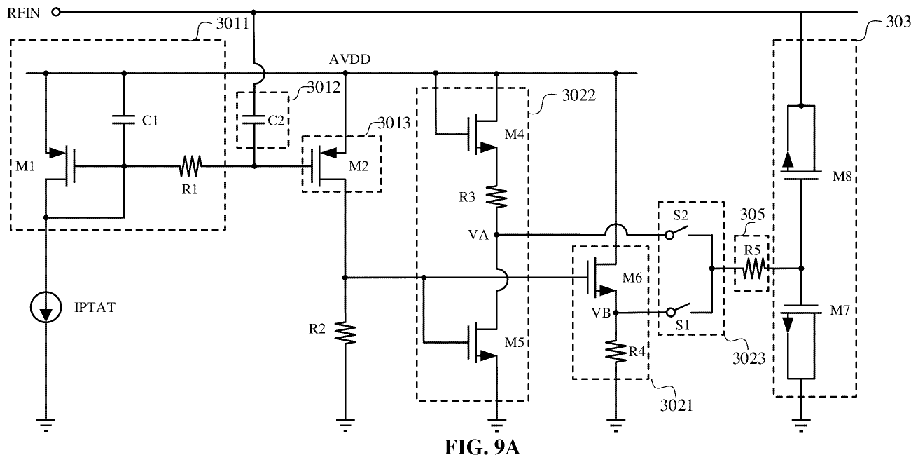

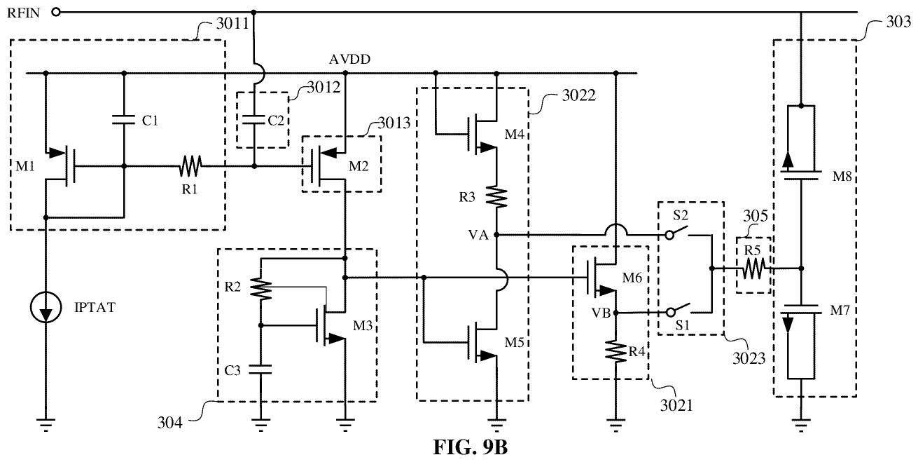

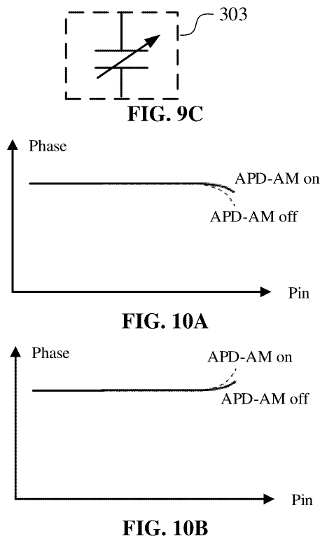

FIG. 7 is the first schematic diagram of a hardware composition including a compensation circuit for an amplifier (APD-PM circuit) according to an embodiment of the present disclosure. FIG. 8A is the second schematic diagram of a hardware composition including a compensation circuit for an amplifier (APD-PM circuit) according to an embodiment of the present disclosure. FIG. 8B is a schematic diagram of a connection relationship between a compensation circuit for an amplifier (APD-PM circuit) and the amplifier according to an embodiment of the present disclosure. FIG. 9A is the first schematic diagram including a compensation circuit for an amplifier (APD-PM circuit) according to an embodiment of the present disclosure. FIG. 9B is the second schematic diagram including a compensation circuit for an amplifier (APD-PM circuit) according to an embodiment of the present disclosure. FIG. 9C is the third schematic diagram including a compensation circuit for an amplifier (APD-PM circuit) according to an embodiment of the present disclosure. The compensation circuit for the amplifier (APD-PM circuit) will be described in detail below with reference to FIG. 7 to FIG. 9C.

The embodiments of the present disclosure provide a compensation circuit for an amplifier. As illustrated in FIG. 7, the compensation circuit 300 of the amplifier includes a detection circuit 301, a control circuit 302, and a phase compensation circuit 303. The detection circuit 301 is connected to an input end of the amplifier, and is configured to detect an input power of an input signal of the amplifier. The control circuit 302 is connected to the detection circuit 301, and is configured to output a control signal according to the detected input signal. The phase compensation circuit 303 is connected to an output end of the control circuit 302, and is configured to change the capacitance between the input end of the amplifier and the ground node according to the control signal, to compensate for the phase of the amplifier in different directions. As illustrated in FIG. 8B, the compensation circuit 200 of the amplifier (APD-PM circuit) in the embodiment of the present disclosure may be connected to the input end of the input matching circuit of the amplifier, and the integration may be implemented in the RF front-end module. Similarly to the APD-AM circuit, the compensation circuit 200 may also be located at other positions of the amplifier, such as the input end of the driver stage amplifier. There may be multiple compensation circuits, which will not be elaborated here.

As previously described, the phase change of the amplifier is associated with the input power of the amplifier. When the input power is less, the phase linearity is better, and when the input power increases to a certain extent, the phase starts to change, and the phase linearity becomes worse. In the embodiment of the present disclosure, the control signal generated according to the detected input power is associated with the phase change of the amplifier, and the direction of phase compensation may also be indicated. Therefore, the compensation circuit for the amplifier provided in the embodiment of the present disclosure can detect the input power of the input signal of the amplifier through the detection circuit 301, generate the control signal through the control circuit 302, and finally accurately control to intervene the phase compensation in the appropriate direction when the amplifier reaches a certain input power through the phase compensation circuit 303.

Here, the detection circuit 301 is mainly configured to detect the input power Pin of the input signal of the amplifier. In some embodiments, the detection circuit 301 includes a bias circuit 3011, a sampling circuit 3012, and a power measurement circuit 3013. The bias circuit 3011 is connected to the power measurement circuit 3013, and is configured to provide a bias signal to the power measurement circuit. The sampling circuit 3012 is connected to an input end of the amplifier, and is configured to perform sampling on an input signal of the amplifier. The power measurement circuit 3013 is configured to output a detection signal according to the sampled input signal under the action of the bias signal. The detection signal is associated with the input power of the amplifier. The detection signal may be a current signal or a voltage signal, which is substantially the same as that described above, which will not be elaborated herein.

Exemplarily, as illustrated in FIG. 8A, the input signal of the amplifier, i.e., the RF signal RFIN, is coupled into the power measurement circuit 3013 through the sampling circuit 3012. Meanwhile, the bias circuit 3011 provides the second bias signal to the power measurement circuit 3013. After receiving the signals from the bias circuit 3011 and the sampling circuit 3012, the power measurement circuit 3013 outputs a detection signal that may be used to characterize the input power Pin of the input signal of the amplifier. The detection signal is associated with the input power of the amplifier. In some embodiments, the detection signal is a current signal, and the current signal is positively associated with the input power of the amplifier.

In some specific embodiments, the sampling circuit 3012 includes the second capacitor and the power measurement circuit 3013 includes the fourth transistor. One end of the second capacitor is connected to the input end of the amplifier, and the other end of the second capacitor is connected to the control end of the fourth transistor. One controlled end of the fourth transistor is connected to the power supply node, and the other controlled end of the fourth transistor is connected to the control circuit 302.

Here, the adjustment of the amplification factor of the fourth transistor, i.e., the adjustment of the ratio of the power of the detection signal output by the fourth transistor to the input power of the amplifier, may be implemented by adjusting the parameter of the fourth transistor, such as the aspect ratio. It is to be understood that when the input signal is fixed, the greater the amplification factor of the fourth transistor is, the greater the output detection signal is and the stronger the phase compensation effect is, and the less the amplification factor of the fourth transistor is, the less the power of the output detection signal is and the weaker the phase compensation effect is. Based on this, the phase compensation amount may be adjusted by adjusting the parameter of the fourth transistor according to the actual demand.

In some specific embodiments, the fourth transistor may be a P-type MOS transistor. The source of the P-type MOS transistor is connected to the power supply node AVDD, and the drain of the P-type MOS transistor is connected to the control circuit 302.

Exemplarily, as illustrated in FIG. 9A and FIG. 9B, the second capacitor C2 is configured to perform sampling on the input signal of the PA, i.e., the RF signal RFIN. The input signal is coupled into the APD-PM circuit, specifically into the gate of the fourth transistor M2. M2, as a power detection transistor, outputs a detection signal that is associated with the power of the RF signal, and transmits the DC detection signal to the control circuit and the bandwidth compensation circuit (if there is a bandwidth compensation circuit). In the present embodiment, the output detection signal is a current signal, and in other embodiments, the detection signal may be converted into a voltage signal by connecting the fourth transistor with a load in series, which is not limited in the present disclosure.

In some specific embodiments, the bias circuit 3011 includes the fifth transistor. One controlled end of the fifth transistor is connected to the power supply node, and the other controlled end of the fifth transistor is connected to its own control end and connected to the ground node through a current source. A control end of the fifth transistor is connected to the power measurement circuit 2013.

In some specific embodiments, the first bias circuit 2011 further includes the third capacitor and the third resistor. One end of the third capacitor is connected to the power supply node, and the other end of the third capacitor is connected to the control end of the fifth transistor. One end of the third resistor is connected to the control end of the fifth transistor and the third capacitor, and the other end of the third resistor is connected to the power measurement circuit 3013.

In some specific embodiments, the fifth transistor may be a P-type MOS transistor. The source of the P-type MOS transistor is connected to the power supply node AVDD, the drain of the P-type MOS transistor is short circuited to its own gate and connected to the ground node through a current source.

Exemplarily, as illustrated in FIG. 9A and 9B, the fifth transistor M1, the third capacitor C1, and the third resistor R1 are taken as the first bias circuit to provide a desired second bias signal to the power detection tube M2. R1 and C1 form a filter circuit to isolate the RF signal from the DC power supply signal of the power supply node. It should be noted that in some embodiments, the third capacitor C1 and the third resistor R1 may be omitted. When the third capacitor C1 and the third resistor R1 are omitted, the gate of the fifth transistor M1 is directly connected to the power measurement circuit 2013.

In some embodiments, the bias circuit 3011 is connected to the ground node through a current source with a positive temperature coefficient. That is, the other controlled end of the fifth transistor is connected to the ground node through a current source with a positive temperature coefficient.

Exemplarily, as illustrated in FIG. 9A and FIG. 9B, the other controlled end of the fifth transistor M1 is connected to the ground node through a current source IPTAT with a positive temperature coefficient.

It is to be understood that under a condition of high power, the heat generated by the PA will increase, which causes the temperature around PA to rise. After the IPTAT is introduced, when the temperature rises, the IPTAT increases. Under the same condition, the voltage of the gate of M5 (i.e., the first transistor of the gain control circuit 2022) illustrated in FIG. 9A and FIG. 9B is greater, so the compensation amplitude for the PA is greater. In this way, the compensation amplitude of the APD-PM circuit for the PA can be increased under the condition of high power.

Here, the control circuit is mainly used to generate a control signal based on the detected signal, and the control signal may indicate the moment of phase compensation and the direction of phase compensation. In some embodiments, the control circuit 302 includes a sub-control circuit. The sub-control circuit is connected to the detection circuit, and is configured to output a control signal positively and/or negatively associated with the detection signal according to the detection signal.

In some specific embodiments, the control circuit 302 includes at least the first sub-control circuit 3021, the second sub-control circuit 3022 and a switching control circuit 3023. The first sub-control circuit 3021 is connected to the detection circuit 301, and is configured to output the first control voltage that is proportional to the input power of the detected input signal according to the detected signal. The second sub-control circuit 3022 is connected to the detection circuit 301, and is configured to output the second control voltage inversely proportional to the input power of the detected input signal according to the detected input signal. The switching control circuit 3023 is connected to the first sub-control circuit 3021, the second sub-control circuit 3022, and the phase compensation circuit 303, and is configured to control one of the first sub-control circuit 3021 or the second sub-control circuit 3022 to be connected to the phase compensation circuit 303.

Exemplarily, as illustrated in FIG. 8A, the control circuit 302 receives a signal output by the detection circuit 301 for characterizing the input power Pin of the input signal of the amplifier. However, the direction of the signal output by the detection circuit 301 is fixed (for example, increasing with an increase of the input power), it does not indicate the direction of phase compensation (advance or lag), and the moment of starting to perform phase compensation cannot not be well determined. Based on this, in the embodiment of the present disclosure, the first sub-control circuit 3021 and the second sub-control circuit 3022 are set, and the first sub-control circuit 3021 and the second sub-control circuit 3022 may generate the control voltage that varies in different directions depending on the input power of the detected signal to indicate different phase compensation directions. Meanwhile, the first sub-control circuit 3021 and the second sub-control circuit 3022 may start to perform phase compensation when the signal output by the detection circuit 301 indicates that the input power reaches a certain degree, that is, when the phase of the amplifier starts to change.

In the control circuit 302 of FIG. 9A, a suitable static operating point may be set for the first sub-control circuit 3021 and the second sub-control circuit 3022 through R2 in FIG. 9A, so that when the phase of PA starts to change, the compensation for the phase of the amplifier is performed through the APD-PM circuit, that is, the control signal indicates the moment to start to perform the phase compensation.

In some embodiments, the sub-control circuit includes a starting control circuit and a direction control circuit. The starting control circuit is connected to the output end of the detection circuit, and is configured to selectively transmit the detection signal to the direction control circuit according to the detected signal. The direction control circuit is connected to the output end of the starting control circuit, and is configured to generate a control signal that increases with an increase of the input power of the detection signal or decreases with an increase of the input power of the detection signal according to the received output signal of the starting control circuit.

In some specific embodiments, as illustrated in FIG. 9A and FIG. 9B, the starting control circuit of the first sub-control circuit 3021 includes the first transistor M6, and the direction control circuit includes the first resistor R4. The control end of the first transistor M6 is connected to the output end of the detection circuit 301, one controlled end of the first transistor M6 is connected to the power supply node, and the other controlled end of the first transistor M6 is connected to the ground node through the first resistor R4.

In some specific embodiments, the first transistor M6 may be an N-type MOS transistor. The drain of the N-type MOS transistor is connected to the power supply node AVDD, and the source of the N-type MOS transistor is connected to the ground node through the first resistor R4.

Here, the first transistor M6 may be taken as the starting control circuit of the first sub-control circuit 3021. The M6 is turned on when the signal output from the detection circuit 301 indicates that the input power reaches a certain extent, that is, when the phase of the amplifier starts to change, so as to transmit the detected signal to the first resistor R4. The first resistor R4 is taken as the direction control circuit of the first sub-control circuit 3021, and when the output signal of the starting control circuit is received, generates a control signal that increases with an increase of the input power of the detected signal based on the output signal.

In some specific embodiments, as illustrated in FIG. 9A and FIG. 9B, the starting control circuit of the second sub-control circuit 3022 includes the second transistor M5, and the direction control circuit includes the second resistor R3. The control end of the second transistor M5 is connected to the output end of the detection circuit 301, one controlled end of the second transistor M5 is connected to the second resistor R3, and the other controlled end of the second transistor M5 is connected to the ground node. One end of the second resistor R3 is connected to the power supply node, and the other end of the second resistor R3 is connected to the controlled end of the second transistor M5 and the switching control circuit 3023.

In some specific embodiments, the second transistor M5 may be an N-type MOS transistor. The drain of the N-type MOS transistor is connected to the second resistor R2, and the source of the N-type MOS transistor is connected to the ground node.

Here, the second transistor M5 may be taken as the starting control circuit of the second sub-control circuit 3022. The M5 is turned on when the signal output from the detection circuit 301 indicates that the input power reaches a certain extent, that is, when the phase of the amplifier starts to change, so as to transmit the detected signal to the second resistor R3. The second resistor R3 is taken as the direction control circuit of the second sub-control circuit 3022, and when the output signal of the starting control circuit is received, generates a control signal that decreases with an increase of the input power of the detection signal based on the output signal.

In some embodiments, as illustrated in FIG. 9A and FIG. 9B, the second sub-control circuit 3022 further includes the third transistor M4. The control end and one controlled end of the third transistor M4 are both connected to the power supply node, and the other controlled end of the third transistor M4 is connected to the second transistor M5 through the second resistor R3.

In some specific embodiments, the third transistor M4 may be an N-type MOS transistor. The drain and the gate of the N-type MOS transistor are both connected to the power supply node AVDD, and the source of the N-type MOS transistor is connected to the second transistor M5 through the second resistor R2.

Here, the third transistor M4 may consume part of the voltage margin, thereby reducing the time constant at the node VA, which is beneficial for improving the bandwidth. In some embodiments, M4 may be omitted, and in this case, the resistor R3 is directly connected to the power supply node AVDD. It should be noted that when the conduction threshold voltage of the transistor M6 taken as the starting control circuit of the first sub-control circuit and the conduction threshold voltage of the transistor M5 taken as the starting control circuit of the second sub-control circuit are different, the static operating points may be set for M6 and M5 through different circuits, respectively, for example, a control transistor and a resistor are added at the front end of each sub-control circuit (similar to the shift circuit 2021 in FIG. 4B), so that when the phase of PA starts to change, the phase compensation is started to be performed. In some embodiments, the conduction threshold voltages of M6 and M5 may be set to be the same for simplicity of the circuit.

In some embodiments, as illustrated in FIG. 9A and FIG. 9B, the switching control circuit 3023 at least includes the first switch S1 and the second switch S2. The first switch S1 is connected to the first sub-control circuit 3021 and the phase compensation circuit 303, and the second switch S2 is connected to the second sub-control circuit 3022 and the phase compensation circuit 303. When the first switch S1 is in the connected state and the second switch S2 is in the disconnected state, the first sub-control circuit 3021 is controlled to be connected to the phase compensation circuit 303. When the first switch S1 is in the disconnected state and the second switch S2 is in the connected state, the second sub-control circuit 3022 is controlled to be connected to the phase compensation circuit 303.

As illustrated in FIG. 9A and FIG. 9B, the control circuit 302 in the embodiments of the present disclosure may generate a desired control signal by switching of the switch. When S1 is connected and S2 is disconnected, with an increase of the input signal, the gate voltage of M6 increases, the current of M6 increases, and the voltage of R4 increases, thus causing the voltage of VB to rise. When S1 is disconnected and S2 is connected, in the same way, the voltage of M5 increases, the current of M5 increases, the voltage drop of R3 increases, and the voltage of VA decreases.

In some embodiments, the phase compensation circuit 303 is specifically configured to increase the capacitance between the input end of the amplifier and the ground voltage according to the increase of the control signal, and configured to decrease the capacitance between the input end of the amplifier and the ground voltage according to the decrease of the control signal.

In some specific embodiments, the phase compensation circuit 303 is specifically configured to: increase the capacitance between the input end of the amplifier and the ground voltage according to the increases of the first control voltage and the second control voltage; and decrease the capacitance between the input end of the amplifier and the ground voltage according to the decreases of the first control voltage and the second control voltage.

In some embodiments, as illustrated in FIG. 9A and FIG. 9B, the non-linear capacitor network formed by the transistors M7 and M8 enables the equivalent capacitance to ground as seen from the RFIN end to change through the control of the voltage at the VA (VB) node. When S1 is connected and S2 is disconnected, the equivalent capacitance to ground as seen from the RFIN end increases with the increase of the power of the RF signal. When S1 is disconnected and S2 is connected, the equivalent capacitance to ground as seen from the RFIN end decreases with the increase of the power of the RF signal, thereby implementing the compensation for AMPM of PA.

In some specific embodiments, the phase compensation circuit 303 may also be a variable capacitor as illustrated in FIG. 9C, and the switchable switch of the variable capacitor is controlled by the first control signal and the second control signal, thereby adjusting the capacitance.

In the APD-PM circuit provided by the embodiment of the present disclosure, a control circuit is introduced into the APD-PM circuit, which causes the control voltage of the phase compensation circuit 303 to increase or decrease with the increase of the power of the RF signal, so that the equivalent capacitance to the ground as seen from the input end may increase or decrease. The positive compensation (compensation in the advance direction) and negative compensation (compensation in the lag direction) for the phase can be implemented by controlling the capacitance to increase or decrease, so that the versatility of phase compensation is better.

In some embodiments, the compensation circuit 300 of the amplifier further includes a compensation amplitude adjustment circuit 305. Two ends of the compensation amplitude adjustment circuit are connected to the control circuit 302 and the phase compensation circuit 303, respectively, to adjust the amplitude of the phase compensation.

In some specific embodiments, the compensation amplitude adjustment circuit 305 includes the fourth resistor, which is configured to adjust the amplitude of the phase compensation by changing the impedance.

Exemplarily, as illustrated in FIG. 9A and FIG. 9B, an additional control manner for compensation amplitude is provided through the fourth resistor R5. It may be understood that if the resistance of R5 is set too great, such as infinity, it is equivalent to an open circuit and the compensation cannot be performed, and the AMPM circuit is invalid. If the resistance of R5 is set too low, the slope of AMPM curve will be great, which will also cause linearity deterioration. Therefore, an appropriate resistance of R5 can compensate AMPM more smoothly, which is conducive to improving linearity.

In some specific embodiments, the fourth resistor R5 may include a variable resistor.

In some embodiments, the compensation circuit 300 of the amplifier further includes a bandwidth compensation circuit 304. The bandwidth compensation circuit 304 is connected to both the detection circuit 301 and the control circuit 302, and is configured to compensate for the bandwidth of the amplifier.

In some embodiments, the detection signal is a current signal, and the bandwidth compensation circuit 304 is further configured to convert the detection signal into a voltage signal.

In some specific embodiments, as illustrated in FIG. 9B, the bandwidth compensation circuit 304 includes the sixth transistor M3, the third resistor R2, and the first capacitor C3. The third resistor R2 and the first capacitor C3 are connected in series between the output end of the detection circuit 301 and the ground node. The control end of the sixth transistor M3 is connected to both the third resistor R2 and the first capacitor C3, one controlled end of the sixth transistor M3 is connected to the output end of the detection circuit, and the other controlled end of the sixth transistor M3 is connected to the ground node.

In some specific embodiments, the sixth transistor may be an N-type MOS transistor. The drain of the N-type MOS transistor is connected to the output end of the detection circuit, and the source of the N-type MOS transistor is connected to the ground node.

Here, the principle of phase compensation of the bandwidth compensation circuit 304 may be understood with reference to the previous description of the bandwidth compensation circuit 203.

It is to be understood that the bandwidth compensation circuit 304 may increase the bandwidth, but does not affect the subsequent phase compensation. Therefore, when the detection signal is a current signal, the bandwidth compensation circuit is replaced with the ground resistor.

FIG. 10A is the first schematic diagram of compensation for the AMPM curve of PA through the APD-PM circuit according to an embodiment of the present disclosure. FIG. 10B is the second schematic diagram of compensation for the AMPM curve of PA through the APD-PM circuit according to an embodiment of the present disclosure. It should be noted that the abscissa in FIG. 10A and FIG. 10B is the input power of the amplifier, and the ordinate in FIG. 10A and FIG. 10B is the phase of the amplifier. It may be seen that after the APD-PM circuit is started, the phase change rate of PA in different directions is slowed down, and the linearity improvement is obvious.

The embodiments of the present disclosure further provide an amplifier assembly. As illustrated in FIG. 8B, the amplifier assembly includes an amplifier 100 and the compensation circuit for the amplifier 300 (APD-PM circuit) provided by the embodiment of the present disclosure. The compensation circuit for the amplifier is connected to the input end of the amplifier.

In some embodiments, the amplifier 100 may include an input matching circuit, a driver stage amplifier, and a power stage amplifier that are sequentially connected in series. The compensation circuit for the amplifier is connected to the input end of the input matching circuit, or is connected between the input matching circuit and the driver stage amplifier, or is connected between the driver stage amplifier and the power stage amplifier.

It should be noted that when the compensation circuit is connected to different positions in the amplifier circuit, the detection circuit is configured to detect the related input power, i.e., the input end of the amplifier, which may be understood as the RF signal RFIN input end, the input end of the driver stage amplifier, or the input end of the power stage amplifier. The input signal and power are the corresponding signal and input power.

In some embodiments, there may be multiple compensation circuits for the amplifier, and the multiple compensation circuits are connected to different positions of the amplifier.

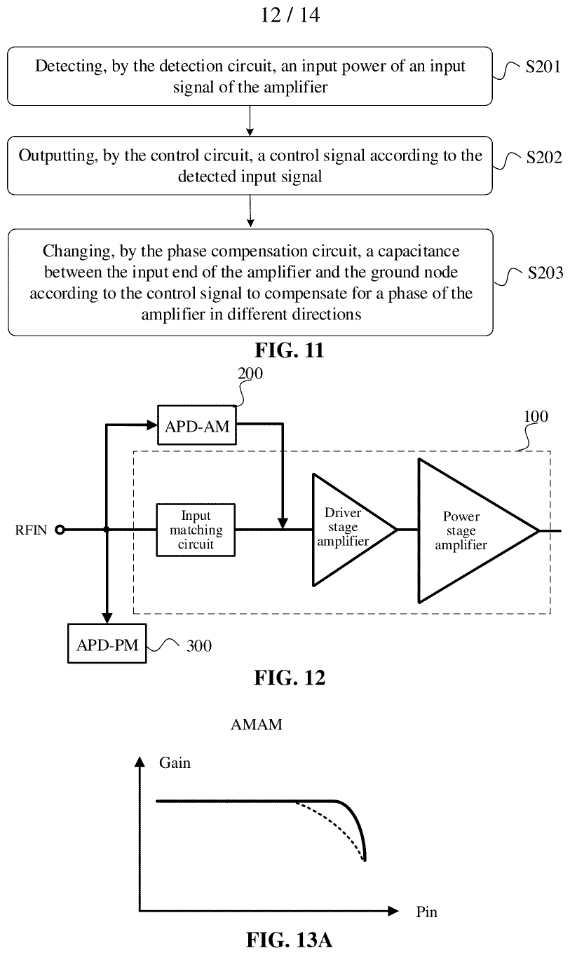

The embodiments of the present disclosure further provide a method for compensating an amplifier. The method is applied to a compensation circuit for the amplifier (APD-PM circuit). The compensation circuit for the amplifier (APD-PM circuit) includes a detection circuit, a control circuit, and a phase compensation circuit. As illustrated in FIG. 11, the method for compensating the amplifier includes the following operations.

In operation S201, the detection circuit detects an input power of an input signal of the amplifier.

In operation S202, the control circuit outputs a control signal according to the detected input signal.

In operation S203, the phase compensation circuit changes a capacitance between the input end of the amplifier and the ground node according to the control signal, so as to compensate for a phase of the amplifier in different directions.

It should be noted that the specific implementation of the compensation circuit for the amplifier (APD-PM circuit), various transistor type parameters, and the like mentioned in the above embodiment of the amplifier assembly and the above embodiment of the method for compensating the amplifier may be understood with reference to the specific implementation of the foregoing compensation circuit for the amplifier (APD-PM circuit), which will not be elaborated here. In some embodiments, as illustrated in FIG. 12, the amplifier assembly further includes an APD-AM circuit 200. The two ends of the APD-AM circuit 200 are connected to the input end of the amplifier and the bias end of the amplifier, respectively, to compensate for the gain of the amplifier.

It should be noted that, when the amplifier assembly includes both the APD-AM circuit 200 and the APD-PM circuit 300, the detection circuit in the APD-AM circuit 200 and the APD-PM circuit 300 is used together. The connection position and number of the APD-AM circuit 200 and the APD-PM circuit 300 may be the same as in the above embodiments, which will not be elaborated herein. In FIG. 12, only the case where the compensation circuit for the amplifier is connected to two ends of the drive stage amplifier and the phase compensation circuit 300 is connected to the input end of the input matching circuit is illustrated.

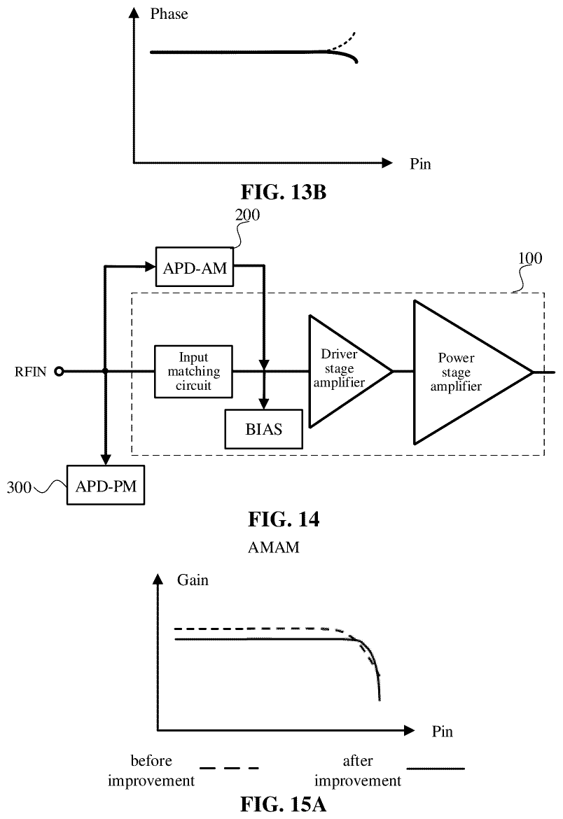

FIG. 13A is the first schematic diagram of compensation for an AMAM curve of PA through an APD-AM circuit and an APD-PM circuit according to an embodiment of the present disclosure. FIG. 13B is the first schematic diagram of compensation for an AMPM curve of PA through an APD-AM circuit and an APD-PM circuit according to an embodiment of the present disclosure. It should be noted that the solid lines in FIG. 13A and FIG. 13B are effect curves corresponding to the embodiment illustrated in FIG. 12, and the dotted curves are effect curves corresponding to the embodiment illustrated in FIG. 1B. The abscissa in FIG. 13A and FIG. 13B is the input power of the amplifier, the ordinate in FIG. 13A is the gain of the amplifier, and the ordinate in FIG. 13B is the phase of the amplifier. It may be seen that both the gain linearity and the phase linearity corresponding to the embodiment illustrated in FIG. 12 are significantly better than the gain linearity and the phase linearity corresponding to the embodiment illustrated in FIG. 1B. The compensation for the phase linearity corresponding to the embodiment illustrated in FIG. 1B is opposite to the actual compensation requirement.

The APD circuit proposed in the embodiment of the present disclosure may include an APD-AM circuit and an APD-PM circuit. The APD-AM circuit mainly implements the “fixed point”, “equivalent value” and “opposite phase” compensation for the PA, thereby maximizing the optimization of the AMAM curve of PA. The compensation for the phase of PA is performed in different directions by the APD-PM circuit to optimize the AMPM curve of PA. Finally, the APD-AM circuit and the APD-PM circuit are used together to complete the compensation for PA, so as to implement the greatly optimization of linearity. Meanwhile, in order to meet the needs of bandwidth, in the embodiment of the present disclosure, the bandwidth compensation technology is introduced in both APD-AM circuit and APD-PM circuit. Finally, an efficient linearity scheme with low cost, low power consumption and high bandwidth for PA is implemented.

In some embodiments, the amplifier further includes the second bias circuit. The second bias circuit is connected to the input end of the amplifier, and is configured to provide the second bias signal to the driver stage amplifier. The bias voltage of the second bias signal is less than the second preset threshold.

The circuit structure in the embodiments of the present disclosure may also implement optimization of the efficiency of the PA or even merit value (linearity and efficiency).

In some embodiments, as illustrated in FIG. 14, the amplifier further includes the second bias circuit BIAS. The second bias circuit BIAS is connected to the bias end of the amplifier, and is configured to provide the second BIAS signal to the amplifier. The bias voltage of the second bias signal is less than the second preset threshold.

Here, the bias voltage of the PA is appropriately lowered under a condition of low power by combining the APD circuit with the bias circuit BIAS of the PA. In this case, the static power consumption of the PA is reduced, the overall efficiency is improved, and accordingly, the overall linearity is also deteriorated. Then, with the help of the APD circuit in the embodiments of the present disclosure, the linearity of the PA is improved, so that the linearity recovers or even exceeds the previous linearity of the PA. Here, the second preset threshold is the bias voltage that is applied to the driver stage amplifier of the PA when the APD is not enabled by the PA.

It should be noted that when the compensation circuits are connected to different positions in the amplifier circuit, the second bias circuit BIAS is connected to the bias end of the amplifier, which may be understood as the bias end of the drive stage amplifier, or the bias end of the power stage amplifier.

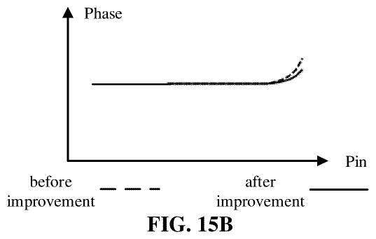

FIG. 15A is the second schematic diagram of compensation for an AMAM curve of PA through an APD-AM circuit and an APD-PM circuit according to an embodiment of the present disclosure. FIG. 15B is the second schematic diagram of compensation for an AMPM curve of PA through an APD-AM circuit and an APD-PM circuit according to an embodiment of the present disclosure. It should be noted that, the solid lines in FIG. 15A and FIG. 15B are effect curves corresponding to the combined use of the APD circuit and the bias circuit BIAS of the PA, and the dotted curves are effect curves corresponding to the absence of combined use of the APD circuit and the bias circuit BIAS of the PA. The abscissa in FIG. 15A and FIG. 15B is the input power of the amplifier, the ordinate in FIG. 15A is the gain of the amplifier, and the ordinate in FIG. 15B is the phase of the amplifier. It can be seen that optimizations of the gain linearity and phase linearity corresponding to the combined use of the APD circuit and the second bias circuit BIAS of PA are obvious. The linearity with the compensation of APD circuit is better than before, so that the optimization of the merit value of PA is implemented.

In the APD circuit provided in the present disclosure, the reference current source of the detection circuit adopts a current source with a temperature coefficient, and the compensation effect of the APD circuit is increased by temperature compensation. The bandwidth compensation circuit is introduced, and the delay of the circuit is reduced and the bandwidth is increased. A suitable static operating point is set, so that the compensation can be intervened at the fixed power point to implement linearity optimization compensation. The APD-PM circuit is introduced to implement the compensation for the phase of the PA, and the compensation direction is adjustable, such that the versatility of APD circuit is improved. The bias circuit of the amplifier itself may be combined to be used to optimize the efficiency and even the merit value.

In the plurality of embodiments provided in the present disclosure, it should be understood that the disclosed device and method may be implemented in other ways. The above embodiments of the device are only schematic, for example, the division of the units is only a logical function division, and in practice, there may be another division manner, for example, multiple units or components may be combined or integrated into another system, or some features may be ignored or not performed. In addition, the coupling, direct coupling or communication connection between various components shown or discussed may be indirect coupling or communication connection through some interfaces, devices or units, and may be electrical, mechanical or other form.

The units illustrated as separate components may or may not be physically separated, and the components displayed as units may or may not be physical units, i.e., may be located in one place, or may be distributed over multiple network units. Part or all of the units may be selected according to the actual needs to implement the purpose of the embodiments.

In addition, various functional units in various embodiments of the present disclosure may be integrated in one processing unit, each unit may exist physically alone, or two or more units may be integrated in one unit. The above integrated unit may be implemented in the form of hardware or in the form of hardware and software functional units.

It should be understood that “detection signal” and “detected signal” mentioned throughout the specification may be used interchangeably, and they are both signal output by the detection circuit. The connection between the two components mentioned throughout the specification may be directly connected between the two components or indirectly connected between the two components through other devices. The “an embodiment” and “one embodiment” mentioned throughout the specification mean that a particular feature, structure, or characteristic related to the embodiment is included in at least one embodiment of the present disclosure. Thus, “in one embodiment” and “in an embodiment” mentioned throughout the specification do not necessarily refer to the same embodiment. Furthermore, these particular features, structures, or characteristics may be incorporated in any suitable manner in one or more embodiments. It should be understood that in various embodiments of the present disclosure, the sequence numbers of the above processes do not mean the sequence of execution, and the sequence of execution of various processes should be determined by its function and internal logic, and should not constitute any limitation on the implementation of the embodiments of the present disclosure. The above serial numbers of the embodiments of the present disclosure are for the purpose of description only, and do not represent the advantages and disadvantages of the embodiments.

It should be noted that, herein, the terms “comprising”, “including” or any other variation thereof are intended to encompass a non-exclusive inclusion, such that processes, methods, articles, or apparatus that include a series of elements include not only those elements, but also other elements that are not explicitly listed, or elements inherent to such processes, methods, articles, or apparatus. Without further limitation, an element defined by the statement “comprising a” does not preclude the presence of additional identical elements in processes, methods, articles, or apparatus that includes the element.

The above description is only the embodiments of the present disclosure. However, the scope of protection of the present disclosure is not limited thereto, and any variations and substitutions that the person skilled in the art can easily conceive within the technical scope disclosed in the present disclosure should be covered within the scope of protection of the present disclosure.

1. A compensation circuit for an amplifier, comprising a detection circuit, a control circuit and a phase compensation circuit, wherein,
the detection circuit is connected to an input end of the amplifier, and is configured to detect an input power of an input signal of the amplifier;
the control circuit is connected to the detection circuit, and is configured to output a control signal according to the detected input signal; and
the phase compensation circuit is connected to an output end of the control circuit, and is configured to change a capacitance between the input end of the amplifier and a ground node according to the control signal, to compensate for a phase of the amplifier in different directions.

2. The compensation circuit for the amplifier of claim 1, wherein the control circuit comprises a sub-control circuit, and the sub-control circuit is connected to the detection circuit, and is configured to output a control signal positively and/or negatively associated with the detection signal according to the detection signal.

3. The compensation circuit for the amplifier of claim 2, wherein the sub-control circuit comprises a starting control circuit and a direction control circuit;
the starting control circuit is connected to an output end of the detection circuit, and is configured to selectively transmit the detection signal to the direction control circuit according to the detected signal; and
the direction control circuit is connected to the starting control circuit, and is configured to generate the control signal that increases with an increase of an input power of the detection signal or decreases with the increase of the input power of the detection signal according to a received output signal of the starting control circuit.

4. The compensation circuit for the amplifier of claim 2, wherein the phase compensation circuit is specifically configured to: increase the capacitance between the input end of the amplifier and a ground voltage according to an increase of the control signal, and decrease the capacitance between the input end of the amplifier and the ground voltage according to a decrease of the control signal.

5. The compensation circuit for the amplifier of claim 2, wherein the control circuit at least comprises a first sub-control circuit, a second sub-control circuit and a switching control circuit,
the first sub-control circuit is connected to the detection circuit, and is configured to output a first control voltage that is proportional to the input power of the detected input signal according to the detected signal;
the second sub-control circuit is connected to the detection circuit, and is configured to output a second control voltage that is inversely proportional to the input power of the detected input signal according to the detected signal; and
the switching control circuit is connected to the first sub-control circuit, the second sub-control circuit, and the phase compensation circuit, and is configured to control one of the first sub-control circuit or the second sub-control circuit to be connected to the phase compensation circuit.

6. The compensation circuit for the amplifier of claim 5, wherein a starting control circuit of the first sub-control circuit comprises a first transistor, and a direction control circuit of the first sub-control circuit comprises a first resistor;
a control end of the first transistor is connected to an output end of the detection circuit, one controlled end of the first transistor is connected to a power supply node, and the other controlled end of the first transistor is connected to the ground node through the first resistor.

7. The compensation circuit for the amplifier of claim 5, wherein a starting control circuit of the second sub-control circuit comprises a second transistor, and a direction control circuit of the second sub-control circuit comprises a second resistor,
a control end of the second transistor is connected to an output end of the detection circuit, one controlled end of the second transistor is connected to the second resistor, and other controlled end of the second transistor is connected to the ground node; and
one end of the second resistor is connected to a power supply node, and other end of the second resistor is connected to the controlled end of the second transistor and the switching control circuit.

8. The compensation circuit for the amplifier of claim 7, wherein the second sub-control circuit further comprises the third transistor, a control end and one controlled end of the third transistor are both connected to the power supply node, and other controlled end of the third transistor is connected to the second transistor through the second resistor.

9. The compensation circuit for the amplifier of claim 5, wherein the switching control circuit at least comprises a first switch and a second switch;
the first switch is connected to the first sub-control circuit and the phase compensation circuit, and the second switch is connected to the second sub-control circuit and the phase compensation circuit;
when the first switch is in a connected state and the second switch is in a disconnected state, the first sub-control circuit is controlled to be connected to the phase compensation circuit; and
when the first switch is in the disconnected state and the second switch is in the connected state, the second sub-control circuit is controlled to be connected to the phase compensation circuit.

10. The compensation circuit for the amplifier of claim 1, further comprising a compensation amplitude adjustment circuit, wherein two ends of the compensation amplitude adjustment circuit are connected to the control circuit and the phase compensation circuit, respectively, to adjust an amplitude of a phase compensation.

11. The compensation circuit for the amplifier of claim 1, further comprising a bandwidth compensation circuit;
wherein the bandwidth compensation circuit is connected to both the detection circuit and the control circuit, and is configured to compensate for a bandwidth of the amplifier.

12. The compensation circuit for the amplifier of claim 1, wherein the detection circuit comprises a bias circuit, a sampling circuit, and a power measurement circuit, wherein,
the bias circuit is connected to the power measurement circuit, and is configured to provide a bias signal to the power measurement circuit;
the sampling circuit is connected to the input end of the amplifier, and is configured to perform sampling on the input signal of the amplifier; and
the power measurement circuit is configured to output a detection signal according to the sampled input signal under an action of the bias signal, and the detection signal is associated with the input power of the amplifier.

13. The compensation circuit for the amplifier of claim 12, wherein the bias circuit is connected to the ground node through a current source with a positive temperature coefficient.

14. An amplifier assembly, comprising:
an amplifier; and
a compensation circuit for the amplifier of claim 1, wherein the compensation circuit for the amplifier is connected to an input end of the amplifier.

15. The amplifier assembly of claim 14, wherein the amplifier comprises an input matching circuit, a driver stage amplifier, and a power stage amplifier that are sequentially connected in series, wherein the compensation circuit for the amplifier is connected to an input end of the input matching circuit, or is connected between the input matching circuit and the driver stage amplifier, or is connected between the driver stage amplifier and the power stage amplifier.

16. The amplifier assembly of claim 15, wherein there are a plurality of compensation circuits for the amplifier, and the plurality of compensation circuits are connected to different positions of the amplifier.

17. The amplifier assembly of claim 14, further comprising a gain compensation circuit, wherein two ends of the gain compensation circuit are connected to the input end of the amplifier and a bias end of the amplifier, respectively, and the gain compensation circuit is configured to compensate for a gain of the amplifier.

18. A method for compensating an amplifier, applied to a compensation circuit for the amplifier comprising a detection circuit, a control circuit and a phase compensation circuit, and the method comprising:
detecting, by the detection circuit, an input power of an input signal of the amplifier;
outputting, by the control circuit, a control signal according to the detected input signal; and
changing, by the phase compensation circuit, a capacitance between an input end of the amplifier and a ground node according to the control signal to compensate for a phase of the amplifier in different directions.
